(19) United States
(12) Patent Application Publication
(10) Pub. No.: US 2023/0212044 A1
(43) Pub. Date: Jul. 6, 2023

(54) UNIT AND METHOD FOR DECOMPOSING OZONE, AND SUBSTRATE TREATING APPARATUS INCLUDING THE UNIT

(71) Applicant: SEMES CO., LTD., Cheonan-si (KR)

(72) Inventors: Bok Kyu Lee, Cheonan-si (KR); Byung Woo Sim, Yongin-si (KR); Yong Sun Ko, Suwon-si (KR); Young Seop Choi, Cheonan-si (KR); Myung A Jeon, Yeosu-si (KR)

(73) Assignee: SEMES CO., LTD., Cheonan-si (KR)

(21) Appl. No.: 18/148,168

(22) Filed: Dec. 29, 2022

(30) Foreign Application Priority Data
Dec. 31, 2021 (KR) 10-2021-0193845

(51) Int. Cl. C02F 1/78

(52) U.S. Cl. CPC C02F 1/78; C02F 2201/005; C02F 2209/001; C02F 2209/02; C02F 2209/23

(57) ABSTRACT

Disclosed is a method of decomposing ozone in ozone water. According to the present invention, a temperature of ozone water is increased by mixing ozone water with heated water, and the ozone in the ozone water is decomposed into oxygen by the increase in the temperature.

### CROSS-REFERENCE TO RELATED APPLICATIONS

This application claims priority to and the benefit of Korean Patent Application No. 10-2021-0193845 filed in the Korean Intellectual Property Office on Dec. 31, 2021, the entire contents of which are incorporated herein by reference.

### TECHNICAL FIELD

The present invention relates to a unit and a method for decomposing ozone in ozone water, and a substrate treating apparatus including the unit.

### BACKGROUND ART

A semiconductor process includes various processes, such as deposition, photography, etching, and cleaning processes. Some of the various processes described above use ozone water. For example, ozone water may be used to remove organic matters on a substrate. Also, ozone water may be used to grow an oxide film on a substrate.

The ozone water used for substrate treatment is discarded after the concentration of ozone is lowered to a set concentration or less. FIG. 1 is a diagram schematically illustrating a structure of a general ozone decomposition unit 900. Referring to FIG. 1, ozone water used for substrate treatment in a treating chamber is introduced into the ozone decomposition unit 900 through a recovery pipe 980. The ozone decomposition unit 900 has a tank 920 in which a circulation pipe 940 is installed, and a pump 942 and a heater 944 are installed in the circulation pipe 940. The ozone water flowing into the tank 920 through the recovery pipe 980 is heated by the heater 944 while flowing along the circulation pipe 940. When the ozone water is heated to a certain temperature, the ozone in the ozone water is decomposed into oxygen and exhausted to the outside of the tank 920 through a vent pipe 950. When the concentration of ozone in the ozone water is lower than the set concentration, the ozone water in the tank 920 is discharged through a drain pipe 960.

However, the ozone decomposition unit of the above structure is not suitable for decomposing ozone in a large amount of ozone water. Since the ozone water flowing along the circulation pipe 940 is heated by the heater 944, it takes a long time to heat a large amount of ozone water to a temperature required for ozone decomposition.

### SUMMARY OF THE INVENTION

The present invention has been made in an effort to provide a unit and a method of decomposing ozone, which are capable of efficiently decomposing ozone in ozone water, and a substrate treating apparatus including the same.

The present invention has been made in an effort to provide a unit and a method of decomposing ozone, which are capable of rapidly decomposing ozone in a large amount of ozone water, and a substrate treating apparatus including the same.

The object of the present invention is not limited thereto, and other objects not mentioned will be clearly understood by those of ordinary skill in the art from the following description.

An exemplary embodiment of the present invention provides an apparatus for treating a substrate, the apparatus including: a treating chamber in which liquid treatment of a substrate is performed by using ozone water; a decomposition unit for decomposing ozone in ozone water; and a recovery pipe for recovering the ozone water treated in the treating chamber to the decomposition unit. The ozone decomposition unit includes: a tank coupled with the recovery pipe and having an internal space to which ozone water is recovered therein; a liquid supply pipe for supplying a liquid to the internal space; and a heating member for heating the liquid.

According to the exemplary embodiment, the liquid supply pipe may be directly connected to the internal space.

According to another example, the liquid supply pipe may be directly connected to the recovery pipe.

According to the exemplary embodiment, the apparatus may further include a controller for controlling a valve installed in the liquid supply pipe and a valve installed in the recovery pipe, in which the controller may control the valve installed in the liquid supply pipe and the valve installed in the recovery pipe so that the ozone water flowing through the recovery pipe starts to be introduced into the internal space in the state where the internal space is filled with the liquid at a certain water level.

According to another example, the apparatus may further include a controller for controlling a valve installed in the liquid supply pipe and a valve installed in the recovery pipe, in which the controller may control the valve installed in the liquid supply pipe and the valve installed in the recovery pipe so that the liquid is supplied to the internal space while the ozone water flowing through the recovery pipe is introduced into the internal space.

According to another example, the apparatus may further include a controller for controlling a valve installed in the liquid supply pipe and a valve installed in the recovery pipe, in which the controller may control the valve installed in the liquid supply pipe and the valve installed in the recovery pipe so that the liquid is supplied from the liquid supply pipe to the recovery pipe while the ozone water is introduced into the internal space through the recovery pipe.

According to the exemplary embodiment, the liquid may include water.

According to the exemplary embodiment, the heating member may heat the liquid to a temperature higher than room temperature and equal to or below a boiling point of the liquid.

According to the exemplary embodiment, a circulation pipe circulating the liquid therein may be connected to the tank, and a heater for heating the ozone water flowing through the circulation pipe may be installed in the circulation pipe.

According to the exemplary embodiment, a drain pipe for discharging ozone water therein may be connected to the tank, a vent pipe for discharging gas generated by decomposition of ozone in the internal space may be connected to the tank, the decomposition unit may include a densitometer for measuring a concentration of ozone in the ozone water in the tank, and when the concentration of ozone measured by the densitometer reaches a set value or less, the ozone water in the internal space may be discharged through the drain pipe.

According to the exemplary embodiment, the apparatus may include two decomposition units, and the recovery pipe may be connected to each of the decomposition units, and the ozone water treated in the treating chamber may be alternately recovered by the two decomposition units.

Another exemplary embodiment of the present invention provides an ozone decomposition unit for decomposing ozone in ozone water, the ozone decomposition unit including: a tank having an internal space to which ozone water is recovered therein; a liquid supply pipe for supplying a liquid to the internal space; and a heating member for heating the liquid.

According to the exemplary embodiment, the liquid may include water.

According to the exemplary embodiment, the ozone water may be introduced into the internal space through a recovery pipe, and the liquid supply pipe may be provided to directly supply the liquid to the internal space.

According to another example, the ozone water may be introduced into the internal space through a recovery pipe, and the liquid supply pipe may be connected to the recovery pipe.

Still another exemplary embodiment of the present invention provides a method of decomposing ozone in ozone water, the method including: increasing a temperature of the ozone water by mixing a heated liquid with the ozone water, in which the ozone in the ozone water is decomposed into oxygen by the increase in the temperature.

According to the exemplary embodiment, after an internal space of a tank is filled with the heated liquid, the ozone water may be introduced into the internal space.

According to the exemplary embodiment, the ozone water may be introduced into an internal space of a tank through a recovery pipe, and a heated liquid may be supplied to the ozone water flowing through the recovery pipe.

According to the exemplary embodiment, the liquid may include water.

According to the exemplary embodiment, the ozone water in the tank may be circulated through a circulation pipe, and the ozone water flowing through the circulation pipe may be heated by a heater installed in the circulation pipe.

According to the exemplary embodiment of the present invention, it is possible to effectively decompose ozone from ozone water used for substrate treatment.

Further, according to the exemplary embodiment of the present invention, it is possible to quickly decompose ozone in ozone water.

The effect of the present invention is not limited to the foregoing effects, and those skilled in the art may clearly understand non-mentioned effects from the present specification and the accompanying drawings.

### BRIEF DESCRIPTION OF THE DRAWINGS

FIG. 1 is a diagram schematically illustrating a structure of a general ozone decomposition unit.

FIG. 2 is a top plan view schematically illustrating a substrate treating apparatus according to an exemplary embodiment of the present invention.

FIG. 3 is a schematic view of one exemplary embodiment of a treating chamber of FIG. 2.

FIG. 4 is a diagram illustrating an example of an ozone decomposition unit.

FIGS. 5 to 9 are diagrams sequentially illustrating an operation process of the ozone decomposition unit of FIG. 4 according to the exemplary embodiment.

FIGS. 10 and 11 are diagrams sequentially illustrating an operation process of the ozone decomposition unit of FIG. 4 according to another exemplary embodiment.

FIG. 12 is a diagram illustrating another example of an ozone decomposition unit.

FIGS. 13 to 15 are views each illustrating a modified example of the ozone decomposition unit of FIG. 4.

### DETAILED DESCRIPTION

Hereinafter, an exemplary embodiment of the present invention will be described in more detail with reference to the accompanying drawings. The exemplary embodiment of the present invention may be modified in various forms, and the scope of the present invention should not be construed as being limited to the following exemplary embodiments. This exemplary embodiment is provided to more completely explain the present invention to those of ordinary skill in the art. Therefore, the shapes of elements in the drawings are exaggerated to emphasize a clearer description.

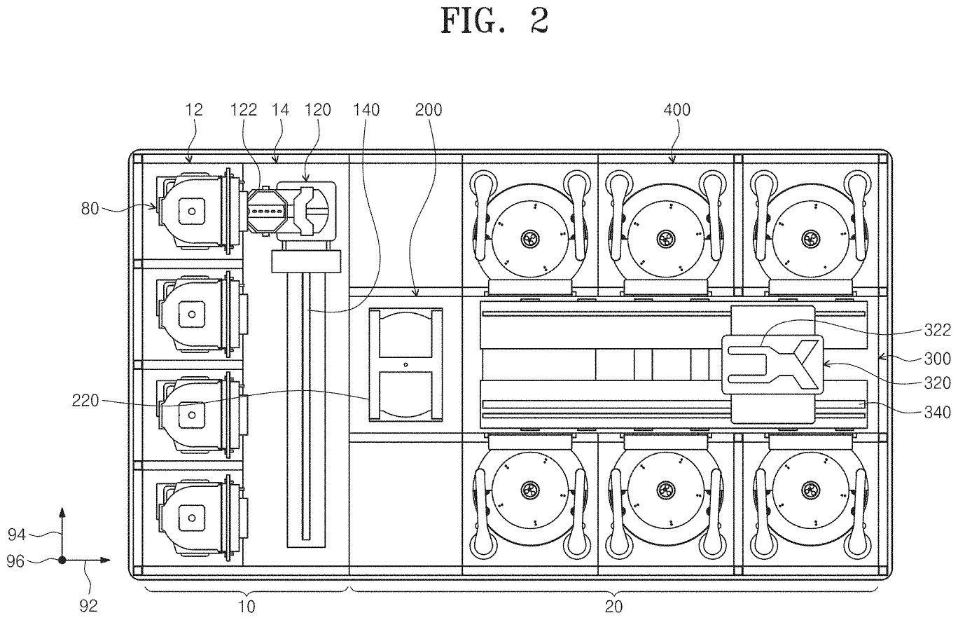

FIG. 2 is a top plan view schematically illustrating a substrate treating apparatus according to an exemplary embodiment of the present invention.

Referring to FIG. 2, a substrate treating apparatus includes an index module 10, a treating module 20, and a controller 30. According to the exemplary embodiment, the index module 10 and the treating module 20 are disposed in one direction. Hereinafter, the direction in which the index module 10 and the treating module 20 are disposed is referred to as a first direction 92, and when viewed from above, a direction vertical to the first direction 92 is referred to as a second direction 94, and a direction vertical to both the first direction 92 and the second direction 94 is referred to as a third direction 96.

The index module 10 transfers a substrate W from a container 80 in which the substrate W is accommodated to the treating module 20, and makes the substrate W, which has been completely treated in the treating module 20, be accommodated in the container 80. A longitudinal direction of the index module 10 is provided in the second direction 94. The index module 10 includes a load port 12 and an index frame 14. Based on the index frame 14, the load port 12 is located at a side opposite to the treating module 20. The container 80 in which the substrates W are accommodated is placed on the load port 12. The load port 12 may be provided in plurality, and the plurality of load ports 12 may be disposed in the second direction 94.

As the container 80, an airtight container, such as a Front Open Unified Pod (FOUP), may be used. The container 80 may be placed on the load port 12 by a transport means (not illustrated), such as an overhead transfer, an overhead conveyor, or an automatic guided vehicle, or an operator.

An index robot 120 is provided to the index frame 14. A guide rail 140 of which a longitudinal is the second direction 94 is provided within the index frame 14, and the index robot 120 may be provided to be movable on the guide rail 140. The index robot 120 includes a hand 122 on which the substrate W is placed, and the hand 122 may be provided to be movable forward and backward, rotatable based on the third direction 96 as an axis, and movable in the third direction 96. The plurality of hands 122 is provided while being spaced apart from each other in the vertical direction, and is capable of independently moving forward and backward.

The treating module 20 includes a buffer unit 200, a transfer chamber 300, and a treating chamber 400. The buffer unit 200 provides a space in which the substrate W loaded to the treating module 20 and the substrate W unloaded from the treating module 20 stay temporarily. The treating chamber 400 performs a treatment process of liquid-treating the substrate W by supplying a liquid onto the substrate W. The transfer chamber 300 transfers the substrate W between the buffer unit 200 and the treating chamber 200.

The transfer chamber 300 may be provided so that a longitudinal direction is the first direction 92. The buffer unit 200 may be disposed between the index module 10 and the transfer chamber 300. A plurality of treating chambers 400 are provided and may be disposed on the side of the transfer chamber 300. The treating chamber 400 and the transfer chamber 300 may be disposed along the second direction 94. The buffer unit 220 may be located at one end of the transfer chamber 300.

According to one example, the treating chambers 400 are respectively disposed on both sides of the transfer chamber 300. At each of both sides of the transfer chamber 300, the treating chambers 400 may be provided in an arrangement of A×B (each of A and B is 1 or a natural larger than 1) in the first direction 92 and the third direction 96, respectively.

The transfer chamber 300 includes a transfer robot 320. A guide rail 340 having a longitudinal direction in the first direction 92 is provided in the transfer chamber 300, and the transfer robot 320 may be provided to be movable on the guide rail 340. The transfer robot 320 includes a hand 322 on which the substrate W is placed, and the hand 322 may be provided to be movable forward and backward, rotatable based on the third direction 96 as an axis, and movable in the third direction 96. A plurality of hands 322 are provided while being vertically spaced apart from each other, and the hands 322 may move forward and backward independently of each other.

The buffer unit 200 includes a plurality of buffers 220 on which the substrate W is placed. The buffers 220 may be disposed while being spaced apart from each other in the third direction 96. A front face and a rear face of the buffer unit 200 are opened. The front face is a face facing the index module 10, and the rear face is a face facing the transfer chamber 300. The index robot 120 may approach the buffer unit 200 through the front face, and the transfer robot 320 may approach the buffer unit 200 through the rear face.

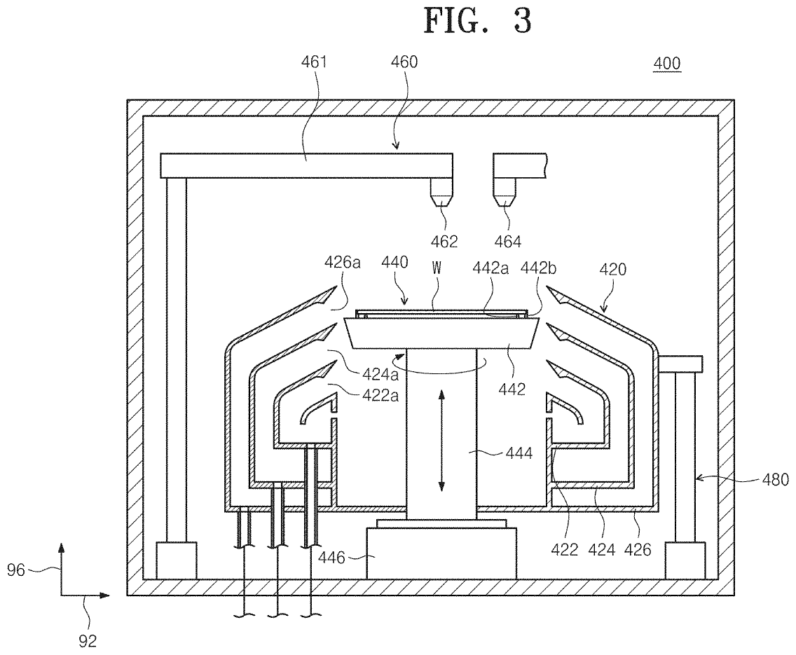

FIG. 3 is a schematic view of one exemplary embodiment of the treating chamber 400 of FIG. 2. Referring to FIG. 3, the treating chamber 400 includes a housing 410, a cup 420, a support unit 440, a nozzle unit 460, a lifting unit 480, an ozone decomposition unit 500, and a controller 600.

The housing 410 is provided in a generally rectangular parallelepiped shape. The cup 420, the support unit 440, and the liquid supply unit 460 are disposed in the housing 410.

The cup 420 has a treating space with an open top, and the substrate W is liquid-treated in the treating space. The support unit 440 supports the substrate W in the treating space. The liquid supply unit 460 supplies the liquid onto the substrate W supported by the support unit 440. The liquid may be provided in a plurality of types, and may be sequentially supplied onto the substrate W. The lifting unit 480 adjusts a relative height between the cup 420 and the support unit 440.

According to one example, the cup 420 includes a plurality of recovery containers 422, 424, and 426. Each of the recovery containers 422, 424, and 426 has a recovery space of recovering the liquid used for the treatment of the substrate. Each of the recovery containers 422, 424, and 426 is provided in a ring shape surrounding the support unit 440. When the liquid treatment process is in progress, the treatment liquid scattered by the rotation of the substrate W may be introduced into the recovery space through inlets 422a, 424a, and 426a of the respective recovery containers 422, 424, and 426 to be described later. According to one example, the cup 420 includes the first recovery container 422, the second recovery container 424, and the third recovery container 426. The first recovery container 422 is disposed to surround the support unit 440, the second recovery container 424 is disposed to surround the first recovery container 422, and the third recovery container 426 is disposed to surround the second recovery container 424. The second inlet 424a through which the liquid is introduced to the second recovery container 424 may be located above the first inlet 422a through which the liquid is introduced to the first recovery container 422, and the third inlet 426a through which the liquid is introduced to the third recovery container 426 may be located above the second inlet 424a.

The support unit 440 includes a support plate 442 and a driving shaft 444. An upper surface of the support plate 442 may be provided in a generally circular shape, and may have a diameter larger than a diameter of the substrate W. A support pin 442a supporting the rear surface of the substrate W is provided to a center portion of the support plate 442, and an upper end of the support pin 442a is provided to protrude from the support plate 442 so that the substrate W is spaced apart from the support plate 442 by a predetermined distance. A chuck pin 442b is provided to an edge of the support plate 442. The chuck pin 442b is provided to protrude upward from the support plate 442, and supports the lateral portion of the substrate W so that the substrate W is not separated from the support unit 440 when the substrate W is rotated. The driving shaft 444 is driven by the driver 446, is connected to the center of the bottom surface of the substrate W, and rotates the support plate 442 based on the central axis thereof.

The nozzle unit 460 includes a first nozzle 462 and a second nozzle 464. The first nozzle 462 supplies ozone water onto the substrate W. The second nozzle 464 supplies a different type of liquid from that of the first nozzle onto the substrate W. For example, the second nozzle may supply pure water onto the substrate.

The first nozzle 462 and the second nozzle 464 are respectively supported on different arms 461, and the arms 461 may be moved independently. Optionally, the first nozzle 462 and the second nozzle 464 may be mounted on the same arm and moved at the same time.

Optionally, the liquid supply unit may further include one or more nozzles in addition to the first nozzle 462 and the second nozzle 464. Additional nozzles may supply different types of treatment liquids to the substrate. For example, the other type of treatment liquid may be an acid solution or a base solution for removing foreign substances on the substrate. In addition, another type of treatment liquid may be alcohol having surface tension lower than that of water. For example, the alcohol may be isopropyl alcohol.

The lifting unit 480 moves the cup 420 in the vertical direction. By the vertical movement of the cup 420, a relative height between the cup 420 and the substrate W is changed. Accordingly, since the recovery containers 422, 424, and 426 for recovering the treatment liquid are changed according to the type of the liquid supplied to the substrate W, the liquids may be separated and collected. Unlike the above, the cup 420 may be fixedly installed, and the lifting unit 480 may move the support unit 440 in the vertical direction.

The ozone decomposition unit 500 decomposes ozone from ozone water used in the treating chamber 400.

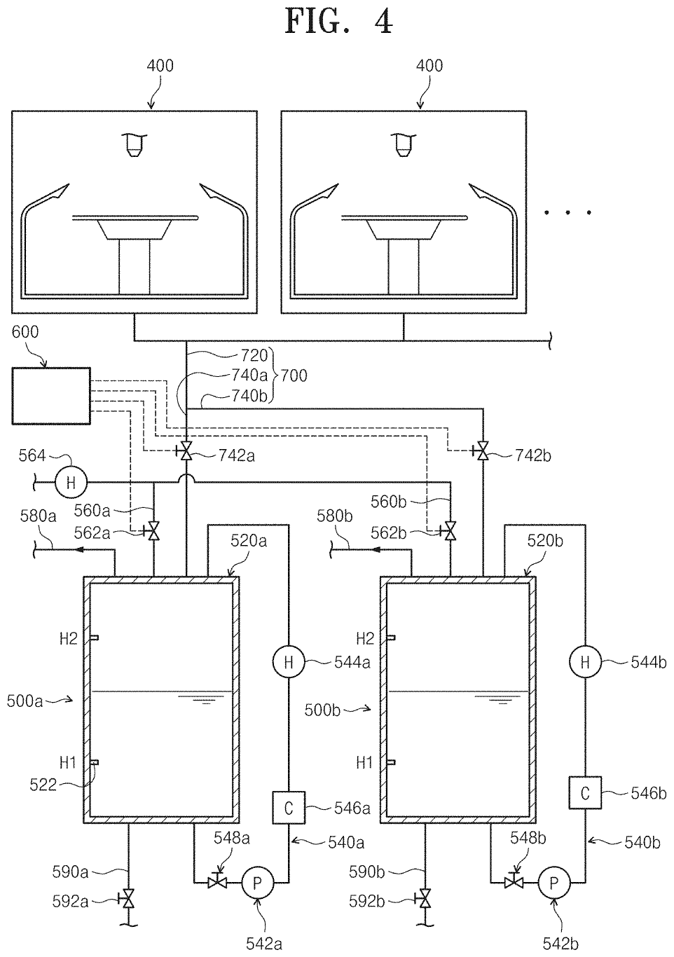

FIG. 4 is a diagram illustrating an example of the ozone decomposition unit. Referring to FIG. 4, a plurality of ozone decomposition units is provided. Hereinafter, a case in which two ozone decomposition units are provided will be described as an example, and the ozone decomposition units will be referred to as a first ozone decomposition unit 500a and a second ozone decomposition unit 500b, respectively.

The ozone water treated in the treating chamber 400 is initially returned to the first ozone decomposition unit 500a. When the first ozone decomposition unit 500a is filled with a set amount of ozone water, the ozone water treated in the treating chamber 400 is returned to the second ozone decomposition unit 500b. Ozone is decomposed from the ozone water filled in the first ozone decomposition unit 500a while the ozone water is recovered by the second ozone decomposition unit 500b. When the concentration of ozone in the ozone water filled in the first ozone decomposition unit 500a is decomposed to a set concentration or below, the ozone water filled in the first ozone decomposition unit 500a is discharged. Thereafter, when the second ozone decomposition unit 500b is filled with a set amount of ozone water, the ozone water is returned to the first ozone decomposition unit 500a again, and ozone is decomposed from the ozone water filled in the second ozone decomposition unit 500b. The decomposition of the ozone water in the first ozone decomposition unit 500a is partially performed while the ozone water is returned to the second ozone decomposition unit 500b as well as the ozone water is returned to the first ozone decomposition unit 500a.

According to the exemplary embodiment, the first ozone decomposition unit 500a and the second ozone decomposition unit 500b have the same structure.

The ozone decomposition units 500a and 500b have tanks 520a and 520b, liquid supply pipes 560a and 560b, and a heating member 564. The tanks 520a and 520b have internal spaces in which ozone water is stored. The ozone water used to treat the substrate in the treating chamber 400 is introduced into internal spaces of the tanks 520a and 520b through a recovery pipe 700. Valves 742a and 742b are installed in the recovery pipe 700. As illustrated in FIG. 4, the recovery pipe 700 may be connected to a plurality of treating chambers 400, and the ozone water discharged from the plurality of treating chambers 400 may be introduced into the tanks 520a and 520b through the recovery pipe 700.

Water level measuring sensors 522 for detecting water levels inside the tank 520a and 520b are installed. The water level measuring sensors 522 detect whether the water levels of the ozone water in the tanks 520a and 520b reach a first set height so that a set amount of ozone water is recovered into the tanks 520a or 520b. In addition, the water level measuring sensors 522 detect whether or not the water levels of the ozone water in the tanks 520a and 520b reach a second set height so that a set amount of liquid described later is supplied into the tanks 520a and 520b. When the liquid is first supplied to the tanks 520a and 520b, and then the ozone water is recovered to the tanks 520a and 520b, one of the water level measuring sensors 522 may detect whether the set amount of liquid is supplied, and the other one of the water level measuring sensors 522 may detect whether the set amount of ozone water is supplied by detecting the entire water level of the ozone water and the liquid.

A plurality of water level measuring sensors 522 may be provided to measure water levels at different heights.

Vent pipes 580a and 580b are connected to the tanks 520a and 520b. The vent pipes 580a and 580b may be provided in an open state to the atmosphere. Oxygen generated by the decomposition of ozone in the ozone water in the tanks 520a and 520b is exhausted to the outside of the tanks 520a and 520b through the vent pipes 580a and 580b.

Drain pipes 590a and 590b are connected to the tanks 520a and 520b. The drain pipes 590a and 590b are coupled to the bottom surfaces of the tanks 520a and 520b. Valves 592a and 592b are installed in the drain pipes 590a and 590b. When the concentration of ozone in the ozone water stored in the tanks 520a and 520b is lower than a set concentration, the ozone water in the tanks 520a and 520b is discharged to the outside of the tanks 520a and 520b through the drain pipes 590a and 590b.

Circulation pipes 540a and 540b are connected to the tanks 520a and 520b. According to one example, one end of the circulation pipe 540a or 540b functions as an inlet and is coupled to the bottom wall of the tank 520a or 520b. The other end of the circulation pipe 540a or 540b functions as an outlet and is located in the internal space of the tank 520a or 520b through the upper wall of the tank 520a or 520b. The other ends of the circulation pipes 540a and 540b are located at a higher level than the water level of the ozone water stored in the tanks 520a and 520b. Optionally, the other ends of the circulation pipes 540a and 540b may be positioned so as to be immersed in the ozone water stored in the tanks 520a and 520b.

Pumps 542a and 542b and heaters 544a and 544b are installed in the circulation pipes 540a and 540b. The pumps 542a and 542b provide fluid pressure so that the liquids in the tanks 520a and 520b flow along the circulation pipes 540a and 540b. The heaters 544a and 544b heat the liquids flowing along the circulation pipes 540a and 540b. According to the example, the heaters 544a and 544b are controlled to heat the liquid to a temperature higher than room temperature and lower than the boiling point of the liquid and ozone water. For example, the heaters 544a and 544b may heat the liquid to a temperature of about 60° C. or more and less than 100° C.

The liquid supply pipes 560a and 560b supply the liquid to the tanks 520a and 520b. According to the example, the liquid may be water. The heating member 564 heats the liquids flowing through the liquid supply pipes 560a and 560b. According to the example, the heating member 564 is installed in the liquid supply pipes 560a and 560b. The heated liquids supplied to the tanks 520a and 520b cause the ozone water introduced into the tanks 520a and 520b to be heated. The heating member 564 heats the liquid to a temperature higher than room temperature. The higher the temperature of the liquid, the faster the temperature of the ozone water rises, whereby the decomposition of ozone becomes faster. Since the liquid may evaporate when the temperature of the heating member 564 is very high, the heating member 564 heats the liquid to a temperature lower than the boiling point of the liquid. For example, the heating member 564 may heat the liquid to a temperature of about 60° C. or more and below 100° C.

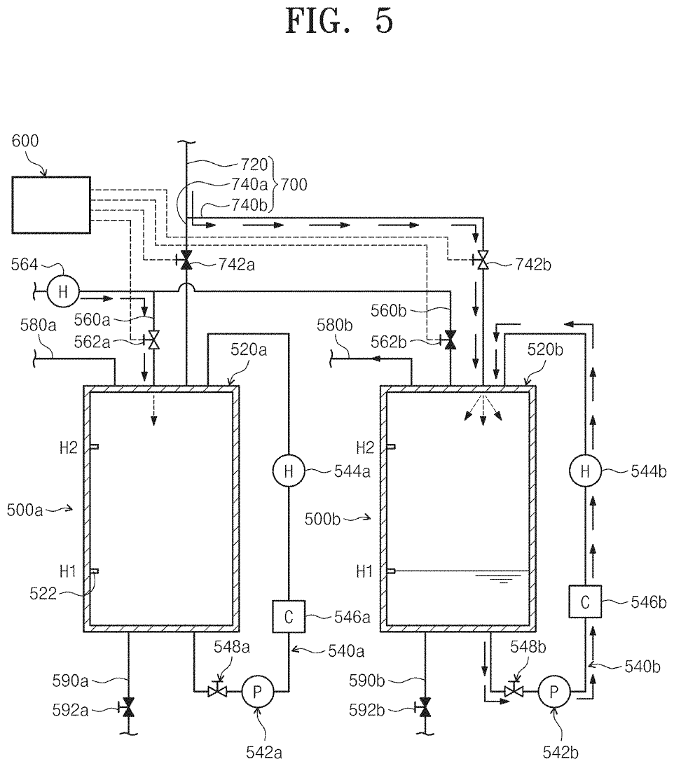

FIGS. 5 to 9 are diagrams sequentially illustrating an operation process of the ozone decomposition unit 500 of FIG. 4 according to the exemplary embodiment. In FIGS. 5 to 9, a valve with an empty inside is an open state, and a valve with a filled inside is a closed state. In addition, in FIGS. 5 to 9, arrows with solid lines show the flow of ozone water or water, and arrows with dotted lines show the exhaust flow of ozone-decomposed gas.

In FIGS. 5 to 8, the case where the first ozone decomposition unit 500a and the second ozone decomposition unit 500b are provided, and the first ozone decomposition unit 500a and the second ozone decomposition unit 500b alternately recover ozone water will be described as an example.

The recovery pipe 700 has a main discharge pipe 720, a first branch pipe 740a, and a second branch pipe 740b. The first branch pipe 740a and the second branch pipe 740b are branched from the main discharge pipe 720. The first branch pipe 740a is connected to the first tank 520a, and the first branch pipe 740a is connected to the second tank 520b. The ozone water discharged from the treating chamber 400 through the main discharge pipe 720 is introduced into the first tank 520a or the second tank 520b through the first branch pipe 740a or the second branch pipe 740b.

Ends of the first branch pipe 740a and the second branch pipe 740b are provided in a tubular shape to supply ozone water to the first tank 520a and the second tank 520b in the form of a stream. Optionally, the first branch pipe 740a and the second branch pipe 740b may be provided in a structure in which ozone water may be supplied to the first tank 520a and the second tank 520b in a spray form. For example, a plurality of minor holes may be formed at the ends of the first branch pipe 740a and the second branch pipe 740b.

Hereinafter, the tank, liquid supply pipe, the vent pipe, the drain pipe, and the circulation pipe related to the first ozone decomposition unit 500a are referred to as the first tank 520a, the first liquid supply pipe 560a, the first vent pipe 580a, the first drain pipe 590a, and the first circulation pipe 540a, and the tank, the liquid supply pipe, the vent pipe, the drain pipe, and the circulation pipe related to the second ozone decomposition unit 500b are referred to as the second tank 520b, the second liquid supply pipe 560b, the second vent pipe 580b, and the second drain pipe. 590b, and the second circulation pipe 540b.

The controller 600 controls valves 548a, 548b, 562a, 562b, 592a, 592b, 742a, and 742b.

Referring to FIG. 5, valves 742a, 562b, 592a, and 592b installed in the first branch pipe 740a, the second liquid supply pipe 560b, the first drain pipe 590a, and the second drain pipe 590b are closed, and the valves 742b, 562a, 548a, and 548b installed in the second branch pipe 740b, the first liquid supply pipe 560a, the first circulation pipe 540a, and the second circulation pipe 540b are opened. Accordingly, the heated water is supplied from the first liquid supply pipe 560a to the first tank 520a while the inside of the first tank 520a is empty. At this time, the ozone water discharged from the treating chamber 400 is recovered to the second tank 520b. The water in the first tank 520a may be circulated through the first circulation pipe 540a and heated by the heaters 544a and 544b while water is being supplied to the first tank 520a. When a set amount of water is supplied to the first tank 520a, the valve 562a installed in the first liquid supply pipe 560a is closed.

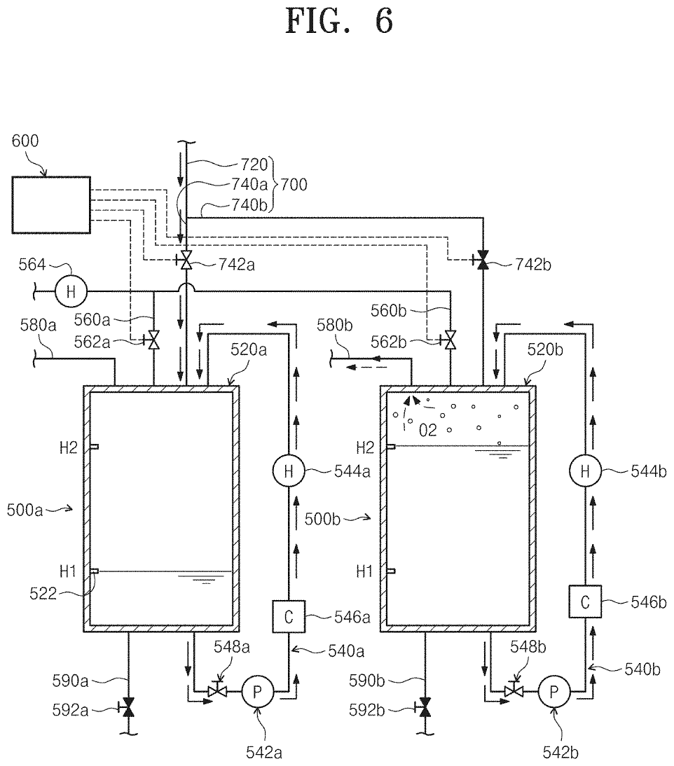

When the set amount of ozone water is recovered to the second tank 520b, the ozone water is recovered to the first tank 520a. Referring to FIG. 6, the valve 742a installed in the first branch pipe 740a is opened, and the valve 742b installed in the second branch pipe 740b is closed. The valves 562a, 562b, 592a, and 592b installed in the first liquid supply pipe 560a, the second liquid supply pipe 560b, the first drain pipe 590a, and the second drain pipe 590b remain closed, and the valves 546a and 546b installed in the first circulation pipe 540a and the second circulation pipe 540b remain open. Since the first tank 520a is filled with water heated to the set temperature, the temperature of the ozone water introduced into the first tank 520a is increased by the heated water. Ozone in the ozone water is decomposed into oxygen by heating, and oxygen in the tanks 520a and 520b is exhausted through the vent pipe 580a. The ozone water in the first tank 520a is continuously circulated through the first circulation pipe 540a and heated by the heater 544a.

The ozone water in the second tank 520b is continuously circulated through the second circulation pipe 540b and heated by the heater 544b while the ozone water is being recovered into the first tank 520a. Oxygen decomposed from ozone in the ozone water in the second tank 520b is exhausted through the second vent pipe 580b. A densitometer 546b installed in the second circulation pipe 540b continuously detects the concentration of ozone in the ozone water.

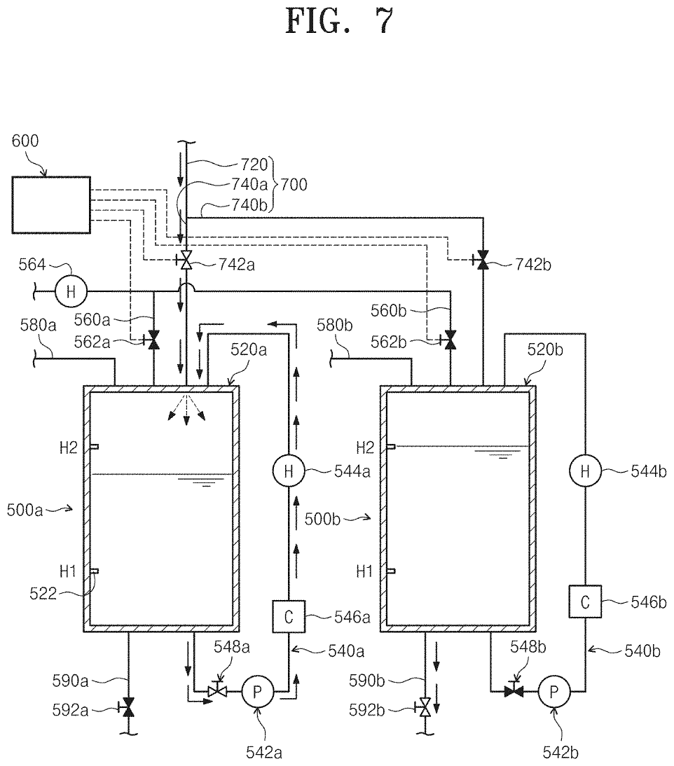

When it is detected that the concentration of ozone in the ozone water in the second circulation pipe 540b is equal to or less than the set concentration, the ozone water in the second tank 520b is discharged through the second drain pipe 590b. Referring to FIG. 7, the valve 592b installed in the second drain pipe 590b is opened, and the valve 546b installed in the second circulation pipe 540b is closed. The valves 742b, 562a, 562b, and 592a installed in the second branch pipe 740b, the first liquid supply pipe 560a, the second liquid supply pipe 560b, and the first drain pipe 590a remain closed, and the valves 742a and 546a installed in the first branch pipe 740a and the first circulation pipe 540a remain open.

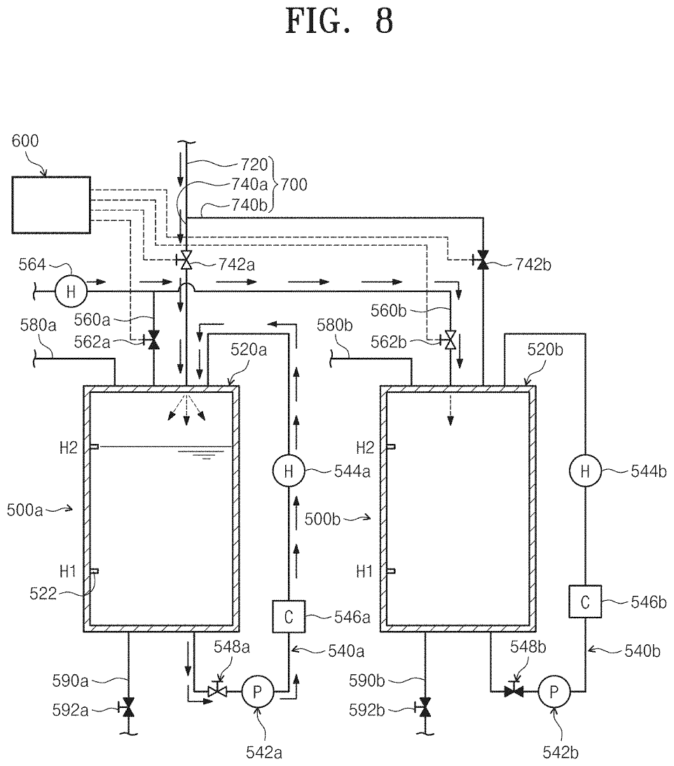

When the discharge of the ozone water is completed from the second tank 520b, a set amount of heated water is supplied to the second tank 520b. Referring to FIG. 8, the valve 592b installed in the second drain pipe 590b is closed, and the valves 562b and 546b installed in the second liquid supply pipe 560b and the second circulation pipe 540b are opened. The valves 742b, 562a, and 592a installed in the second branch pipe 740b, the first liquid supply pipe 560a, and the first drain pipe 590a remain closed, and the valves 742a and 546a installed in the first branch pipe 740a and the first circulation pipe 430a remain open. When the set amount of heated water is filled in the second tank 520b, the valve 562a installed in the first liquid supply pipe 560a is closed.

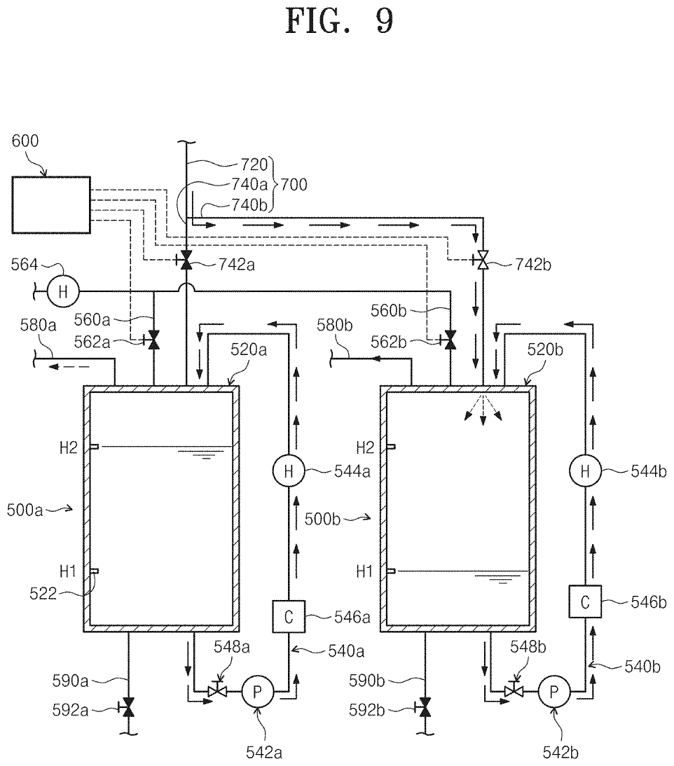

When the set amount of ozone water is introduced into the first tank 520a, the ozone water is recovered to the second tank 520b. Referring to FIG. 9, the valve 742a installed in the first branch pipe 740a is closed, and the valve 742b installed in the second branch pipe 740b is opened. The valves 562a, 562b, 592a, and 592b installed in the first liquid supply pipe 560a, the second liquid supply pipe 560b, the first drain pipe 590a, and the second drain pipe 590b remain closed, and the valves 546a and 546b installed in the first circulation pipe 540a and the second circulation pipe 540b remain open. Ozone is decomposed until the concentration of ozone in the ozone water in the first tank 520a becomes lower than the set concentration while the ozone water is being recovered into the second tank 520b.

The ozone water is alternately returned from the treating chamber 400 to the first tank 520a or the second tank 520b, and ozone is decomposed in the ozone water while repeating the above-described FIGS. 5 to 9.

When it takes a lot of time to reduce ozone in ozone water to a set concentration or less, a large number of ozone decomposition units 500a and 500b are required in the substrate treating apparatus. According to the exemplary embodiment of the present invention, since the ozone water is introduced into the tanks 520a and 520b in a state in which the heated liquid is previously stored in the tanks 520a and 520b, it is possible to reduce the time required for the concentration of ozone in ozone water to decrease to the set concentration.

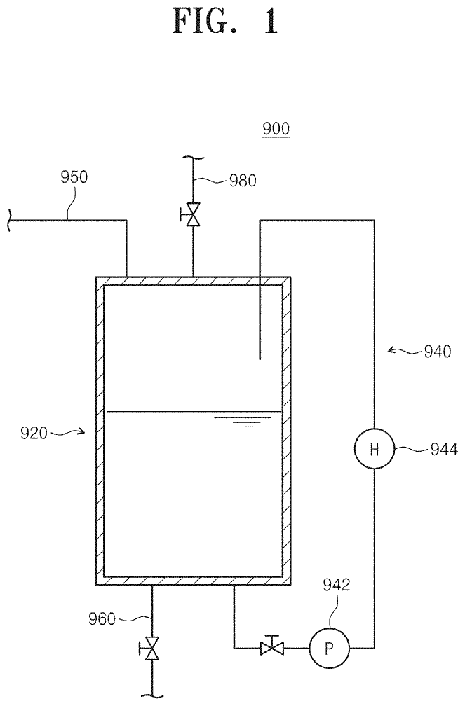

According to the experiment, when 20 L of ozone water was heated to about 60° C. while circulating 20 L of ozone water having an ozone concentration of 100 ppm by using the ozone decomposition unit 900 of FIG. 1, it took about 205 seconds for the ozone concentration to drop to 5 ppm. However, when ozone was decomposed in the same manner as in FIGS. 5 to 9 by using the ozone decomposition units 500a and 500b of FIG. 4, it took about 86 seconds for the concentration of ozone to drop to 5 ppm in ozone water. In this case, the concentration of ozone in the ozone water, the amount of ozone water, and the temperature of the heater installed in the circulation pipe were set to be the same as when ozone was decomposed by using the ozone decomposition unit 900 of FIG. 1, and the temperature of the water supplied through the liquid supply pipe was 60° C. and the set amount of water was 20 L.

Therefore, according to the present exemplary embodiment, a large amount of ozone water generated in the treating chamber 400 may be decomposed without increasing the number of ozone decomposition units 500a and 500b.

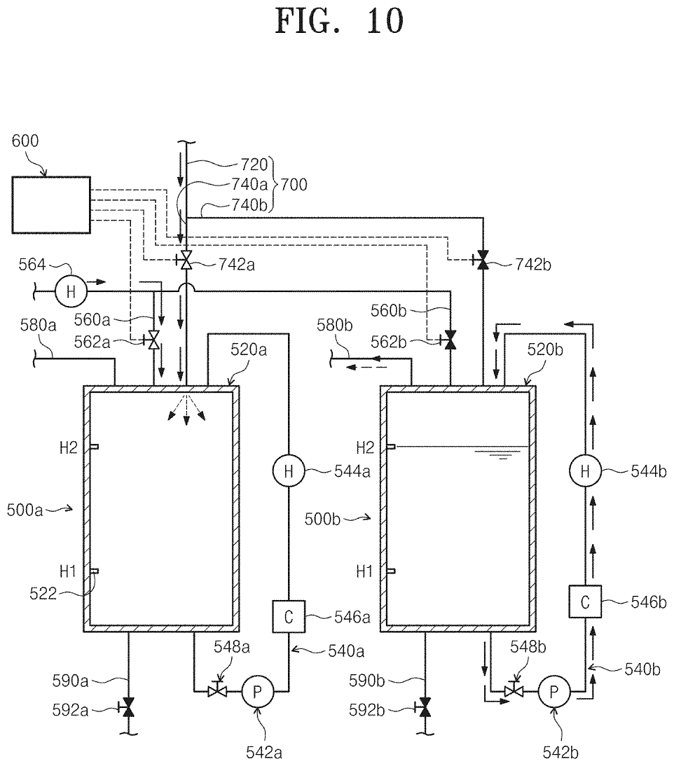

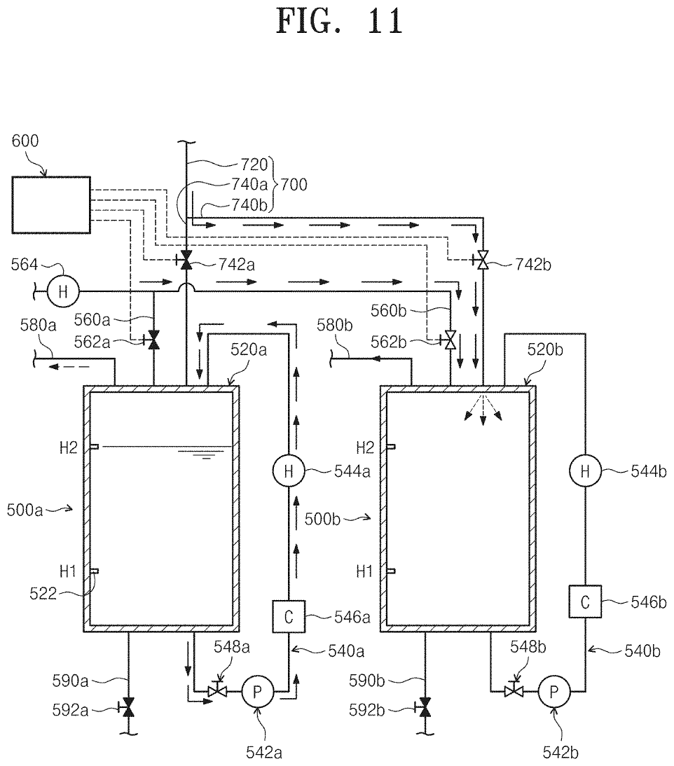

FIGS. 10 and 11 sequentially illustrate an operation process of the ozone decomposition unit of FIG. 4 according to another exemplary embodiment. In FIGS. 10 and 11, a valve with an empty inside is an open state, and a valve with a filled inside is a closed state. In addition, in FIGS. 10 and 11, arrows with solid lines show the flow of ozone water or water, and arrows with dotted lines show the exhaust flow of ozone-decomposed gas.

In the exemplary embodiments of FIGS. 5 to 9, it has been described that ozone water is recovered to the tanks 520a and 520b while the tanks 520a and 520b are filled with the set amount of the heated liquid. However, in the exemplary embodiments of FIGS. 10 and 11, heated water is supplied to the tanks 520a and 520b where the recovery is taking place while the ozone water is being recovered to the tanks 520a and 520b.

Referring to FIG. 10, heated water is supplied to the first tank 520a through the first liquid supply pipe 560a while ozone water is being recovered to the first tank 520a. In this case, in the second tank 520b, ozone is decomposed from the ozone water previously recovered to the second tank 520b. The ozone water in the second tank 520b continues to be circulated through the second circulation pipe 540b. When the concentration of ozone in the ozone water in the second tank 520b is equal to or less than the a value, the ozone water in the second tank 520b is discharged through the second drain pipe 590b.

The supply period of the liquid supplied through the first liquid supply pipe 560a does not have to coincide with the period during which the ozone water is recovered through the first branch pipe 740a. For example, the valves installed in the first branch pipe 740a and the first liquid supply pipe 560a are simultaneously opened, and when the set amount of ozone water is recovered to the first tank 520a, the valve 742a installed in the first branch pipe 740a is closed first. When a set amount of heated water is also supplied to the first tank 520a, the valve 562a installed in the first liquid supply pipe 560a is closed. Alternatively, the valves 742a and 562a may operate in the reverse order.

When both the set amount of ozone water and heated water is introduced into the first tank 520a, the ozone water is recovered from the treating chamber 400 to the second tank 520b, and the heated water is supplied to the second tank 520b as illustrated in FIG. 11. In the first tank 520a, ozone is decomposed from the ozone water in the first tank 520a.

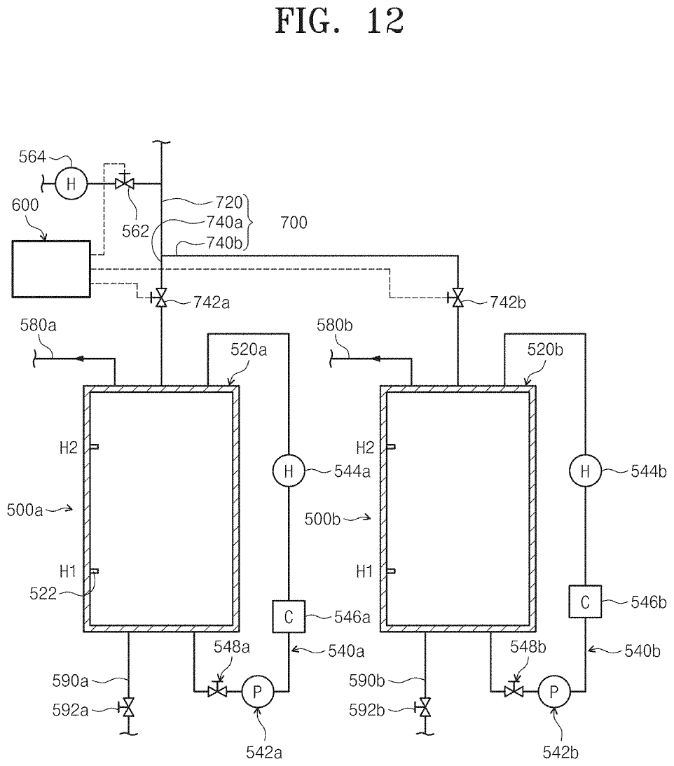

In the above examples, it has been described that the liquid supply pipes 560a and 560b are directly connected to the tanks 520a and 520b. However, unlike this, the liquid supply pipe 560 may be directly connected to the recovery pipe 700 as illustrated in FIG. 12.

According to one example, the liquid supply pipe 560 is connected to the main discharge pipe 720 of the recovery pipe 700. When the ozone water flows from the treating chamber 400 through the main discharge pipe 720, the liquid supply pipe 560 supplies heated water to the main discharge pipe 720. Therefore, the ozone water is introduced into the first tank 520a or the second tank 520b together with the heated water. Alternatively, the liquid supply pipe 560 may be connected to the first branch pipe 740a and the second branch pipe 740b of the recovery pipe 700, respectively.

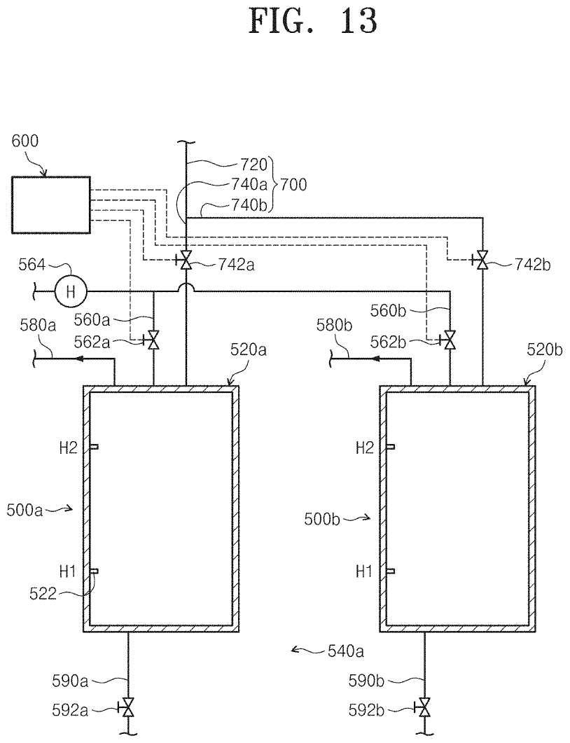

In the above-described example, it has been described that the circulation pipes 540a and 540b are connected to the tanks 520a and 520b, and the ozone water in the tanks 520a and 520b is continuously heated while circulating through the circulation pipes 540a and 540b while ozone is decomposed from the ozone water. However, unlike this, as illustrated in FIG. 13, no circulation pipe is provided in the tanks 520a and 520b, and the ozone water in the tanks 520a and 520b may be heated only by the heated water.

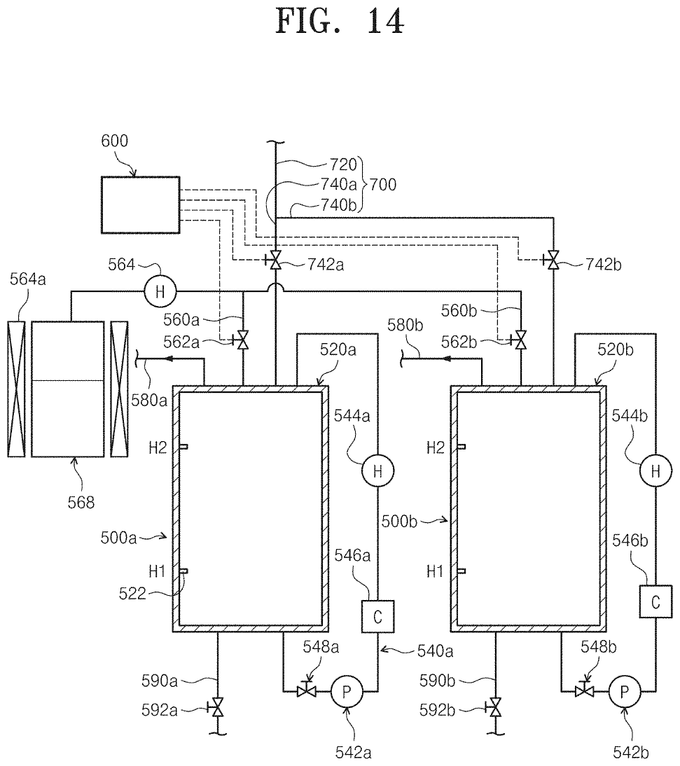

In addition, in the above-described example, it has been described that the heating member 564 is installed in the liquid supply pipes 560a, 560b, and 560 to heat water. Alternatively, however, as illustrated in FIG. 14, the heating member 564a may be provided to a storage tank 568 which is connected to the liquid supply pipes 560a, 560b, and 560 to store water.

In addition, heating members 565a and 565b are additionally installed in the tanks 520a and 520b, and the ozone water in the tanks 520a and 520b may be continuously heated by the heating members 565a and 565b while ozone is decomposed in the ozone water in the tanks 520a and 520b.

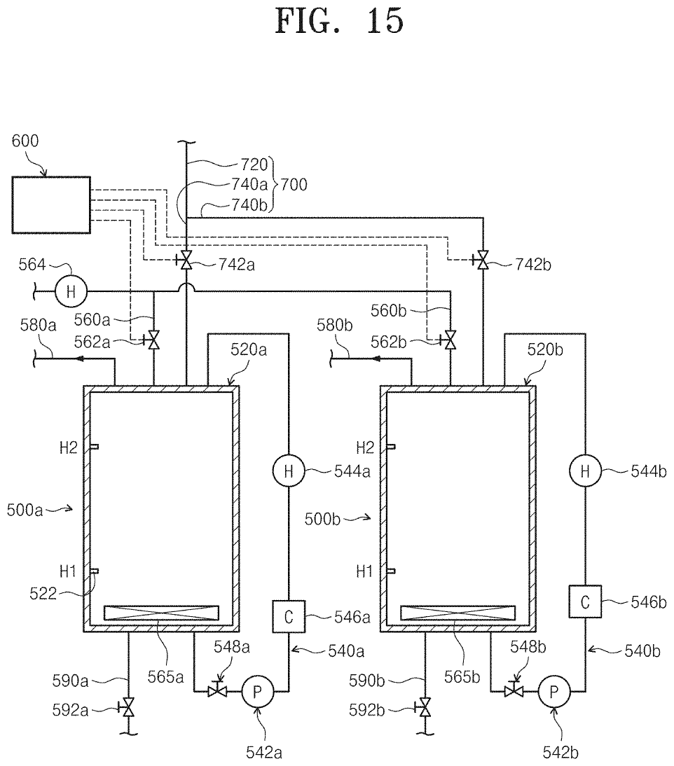

In addition, in the exemplary embodiments of FIGS. 5 to 9, it has been described that heated water is supplied to the tanks 520a and 520b through the liquid supply pipes 560a and 560b. However, unlike this, as illustrated in FIG. 15, when the heating member 564 is installed in the tanks 520a and 520b and water at room temperature is supplied to the tanks 520a and 520b from the liquid supply pipes 560a and 560b, the water in the tanks 520a and 520b may be heated by the heating member 564 before the ozone water is introduced.

In the above example, it has been described that two ozone decomposition units are provided, and ozone water is alternately recovered to the two ozone decomposition units. Alternatively, unlike this, the number of ozone decomposition units is greater than two, and ozone water may be alternately recovered by the plurality of ozone decomposition units. Optionally, only one ozone decomposition unit may be provided.

In addition, in the above example, the structure in which the ozone decomposition unit is coupled to the treating chamber through the recovery pipe has been described as an example. Alternatively, unlike this, the ozone decomposition unit may be provided independently without being coupled to the treating chamber.

In addition, the technical concept of the present invention may be applied not only to decompose ozone water used in an apparatus for treating a substrate, but also to decompose ozone water used in other types of devices.

The foregoing detailed description illustrates the present invention. In addition, the above description shows and describes the exemplary embodiments of the present invention, and the present invention may be used in various other combinations, modifications, and environments. That is, changes or modifications are possible within the scope of the concept of the invention disclosed herein, the scope equivalent to the written disclosure, and/or within the scope of skill or knowledge in the art. The foregoing exemplary embodiment describes the best state for implementing the technical spirit of the present invention, and various changes required in specific application fields and uses of the present invention are possible. Accordingly, the detailed description of the invention above is not intended to limit the invention to the disclosed exemplary embodiment. In addition, the appended claims should be construed to include other exemplary embodiments as well.

What is claimed is:

1. An apparatus for treating a substrate, the apparatus comprising:
a treating chamber in which liquid treatment of a substrate is performed by using ozone water;
a decomposition unit for decomposing ozone in ozone water; and
a recovery pipe for recovering the ozone water treated in the treating chamber to the decomposition unit,
wherein the decomposition unit includes:
a tank coupled with the recovery pipe and having an internal space to which ozone water is recovered therein;
a liquid supply pipe for supplying a liquid to the internal space; and
a heating member for heating the liquid.

2. The apparatus of claim 1, wherein the liquid supply pipe is directly connected to the internal space.

3. The apparatus of claim 1, wherein the liquid supply pipe is directly connected to the recovery pipe.

4. The apparatus of claim 2, further comprising:
a controller for controlling a valve installed in the liquid supply pipe and a valve installed in the recovery pipe,
wherein the controller controls the valve installed in the liquid supply pipe and the valve installed in the recovery pipe so that the ozone water flowing through the recovery pipe starts to be introduced into the internal space in the state where the internal space is filled with the liquid at a certain water level.

5. The apparatus of claim 2, further comprising:
a controller for controlling a valve installed in the liquid supply pipe and a valve installed in the recovery pipe,
wherein the controller controls the valve installed in the liquid supply pipe and the valve installed in the recovery pipe so that the liquid is supplied to the internal space while the ozone water flowing through the recovery pipe is introduced into the internal space.

6. The apparatus of claim 3, further comprising:
a controller for controlling a valve installed in the liquid supply pipe and a valve installed in the recovery pipe,
the controller controls the valve installed in the liquid supply pipe and the valve installed in the recovery pipe so that the liquid is supplied from the liquid supply pipe to the recovery pipe while the ozone water is introduced into the internal space through the recovery pipe.

7. The apparatus of claim 1, wherein the liquid includes water.

8. The apparatus of claim 7, wherein the heating member heats the liquid to a temperature higher than room temperature and equal to or below a boiling point of the liquid.

9. The apparatus of claim 1, wherein a circulation pipe circulating the liquid therein is connected to the tank, and
a heater for heating the ozone water flowing through the circulation pipe is installed in the circulation pipe.

10. The apparatus of claim 9, wherein a drain pipe for discharging ozone water therein is connected to the tank,
a vent pipe for discharging gas generated by decomposition of ozone in the internal space is connected to the tank,
the decomposition unit includes a densitometer for measuring a concentration of ozone in the ozone water in the tank, and
when the concentration of ozone measured by the densitometer reaches a set value or less, the ozone water in the internal space is discharged through the drain pipe.

11. The apparatus of claim 1, wherein the apparatus includes two decomposition units, and
the recovery pipe is connected to each of the decomposition units, and
the ozone water treated in the treating chamber is alternately recovered by the two decomposition units.

12. An ozone decomposition unit for decomposing ozone in ozone water, the ozone decomposition unit comprising:
a tank having an internal space to which ozone water is recovered therein;
a liquid supply pipe for supplying a liquid to the internal space; and
a heating member for heating the liquid.

13. The ozone decomposition unit of claim 12, wherein the liquid includes water.

14. The ozone decomposition unit of claim 12, wherein the ozone water is introduced into the internal space through a recovery pipe, and
the liquid supply pipe is provided to directly supply the liquid to the internal space.

15. The ozone decomposition unit of claim 12, wherein the ozone water is introduced into the internal space through a recovery pipe, and
the liquid supply pipe is connected to the recovery pipe.

16-20. (canceled)
